(19) United States
(12) Patent Application Publication
(10) Pub. No.: US 2025/0351523 A1
(43) Pub. Date: Nov. 13, 2025

(54) SEMICONDUCTOR DEVICE AND METHOD FOR FABRICATING THE SAME

(71) Applicant: United Microelectronics Corp., Hsinchu (TW)

(72) Inventors: Shin-Hung LI, Nantou County (TW); Shan-Shi Huang, Hsinchu City (TW)

(21) Appl. No.: 18/736,599

(22) Filed: Jun. 7, 2024

(30) Foreign Application Priority Data
May 7, 2024 (TW) 113116823

(51) Int. Cl. H01L 29/417; H01L 29/06; H01L 29/66

(52) U.S. Cl. CPC H10D 64/259; H10D 30/0223; H10D 62/102; H10D 64/256

(57) ABSTRACT

A semiconductor device includes: a substrate, a gate structure, a source region, a drain region, a gate contact structure, a source contact structure and a drain contact structure. The gate structure, source region and drain region are all disposed in the substrate. The gate contact structure lands on a gate landing region over the gate structure and electrically contacts with the gate structure. The source contact structure lands on a source landing region over the source region and electrically contacts with the source region. The drain contact structure lands on a drain landing region over the drain region and electrically contacts with the drain region. Wherein, at least one of the source landing region and the drain landing region at least partially overlaps with the gate landing region in an arranging direction of the source region and the drain region.

This application claims the benefit of Taiwan Application Serial No. 113116823 filed at May 7, 2024 the subject matter of which is incorporated herein by reference.

### BACKGROUND

### Technical Field

The disclosure relates to a semiconductor device and the method for fabricating the same, and more particularly to a transistor device and the method for fabricating the same.

### Description of Background

Field-Effect transistor (FET) devices in a semiconductor integrated circuit may generate high leakage current when the source and drain are in the off state (I-off), due to the band-to-band tunneling effect between the drain and gate insulators. It may result in the occurrence of Gate Induced Drain Leakage (GIDL), specially under high drain-gate bias, causing the charge in the FET device used to store information to leak rapidly.

To take the FET devices applied in a pixel unit of an active-matrix organic light-emitting diode (AMOLED) display as an example, when GIDL occurs in the FET devices, the information (the charge in the FET devices) must be restored within a very short refresh time, otherwise the information input to the pixel unit will be lost. However, with the gradual increase of display pixel density (pixel-per-inch, PPI), GIDL of the FET devices not only increases the difficulty of controlling and operating the AMOLED display, but also increases the overall leakage current of the active matrix, so as to cause the power consumption of the AMOLED display rising sharply.

Although an offset gate technology, moving the gate closer to the source terminal to reduce the field by increasing the distance between the gate and the drain terminal or by reducing the width of the gate, had been applied by the industry. But, if the distance between the gate and the drain terminal of the FET devices may be increased, the width of the pixel unit will be increased, thereby reducing the pixel density. Alternatively, if the gate width of the FET devices is reduced, making it substantially smaller than the channel length, it may adversely affect the alignment of the gate contact structure of the FET devices, thereby reducing the process yield of the pixel unit. How to effectively shrink the size of the semiconductor devices without affecting the yield of semiconductor devices has become an important issue in the field of semiconductor technology.

Therefore, there is a need of providing semiconductor device and the method for fabricating the same to obviate the drawbacks encountered from the prior art.

### SUMMARY

One aspect of the present disclosure is to provide a semiconductor device includes: a substrate, a gate structure, a source region, a drain region, a gate contact structure, a source contact structure and a drain contact structure. The gate structure, source region and drain region are all disposed in the substrate. The gate contact structure lands on a gate landing region over the gate structure and electrically contacts with the gate structure. The source contact structure lands on a source landing region over the source region and electrically contacts with the source region. The drain contact structure lands on a drain landing region over the drain region, and electrically contacts with the drain region. Wherein, at least one of the source landing region and the drain landing region at least partially overlaps with the gate landing region in an arranging direction of the source region and the drain region.

Another aspect of the present disclosure is to provide a method for fabricating a semiconductor device, wherein the method includes steps as follows: Firstly, a substrate is provided, a gate structure is then formed on the substrate. Then a source region and a drain region are formed in the substrate. A gate contact structure is formed landing on a gate landing region above the gate structure, and electrically contacting with the gate structure. A source contact structure is formed landing on a source landing region above the source region, and electrically contacting with the source region. A drain contact structure is formed landing on a drain landing region above the drain region, and electrically contacting with the drain region. Wherein, at least one of the source landing region and the drain landing region at least partially overlaps with the gate landing region in an arranging direction of the source region and the drain region.

In accordance with the aforementioned embodiments of the present disclosure, a semiconductor device and a method for fabricating the same are provided, wherein the semiconductor device includes a transistor having a gate landing region, a source landing region and a drain landing region, and each of these three at least partially overlaps with a channel doping region of the transistor. By changing the position of a gate landing region in a manner of at least partially overlapping the channel doping region of the transistor, the gate landing region can at least partially overlap with at least one of the source landing region and the drain landing region in an arranging direction of the source region and the drain region without changing the width of the channel doping region and without shortening the width of the gate region.

Since this approach neither changes the width of the channel doping region nor shortens the width of the gate region, while the gate width of the transistor is reduced, thus the length of the gate structure of the transistor can be reduced without increasing the current leakage of the transistor and without affecting the alignment accuracy of the gate contact structure thereof. Such that the overall size of semiconductor device applying the transistor can be minimized.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A to FIG. 1D are diagrams illustrating a series of process structures for fabricating a semiconductor device, according to one embodiment of the present disclosure;

FIG. 2 is a top view illustrating the structure of the semiconductor device as depicted in FIG. 1D; and

FIG. 3 is a top view illustrating the structure of a traditional semiconductor device.

### DETAILED DESCRIPTION

The embodiments as illustrated below provide a semiconductor device and the method for fabricating the same, which can minimize the overall size of semiconductor device without increasing the current leakage and without affecting the alignment accuracy of the gate contact structure thereof. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

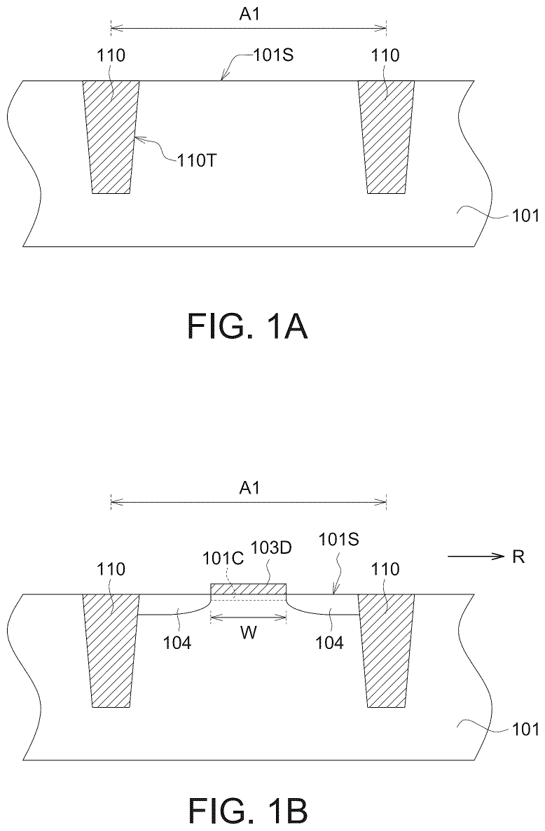

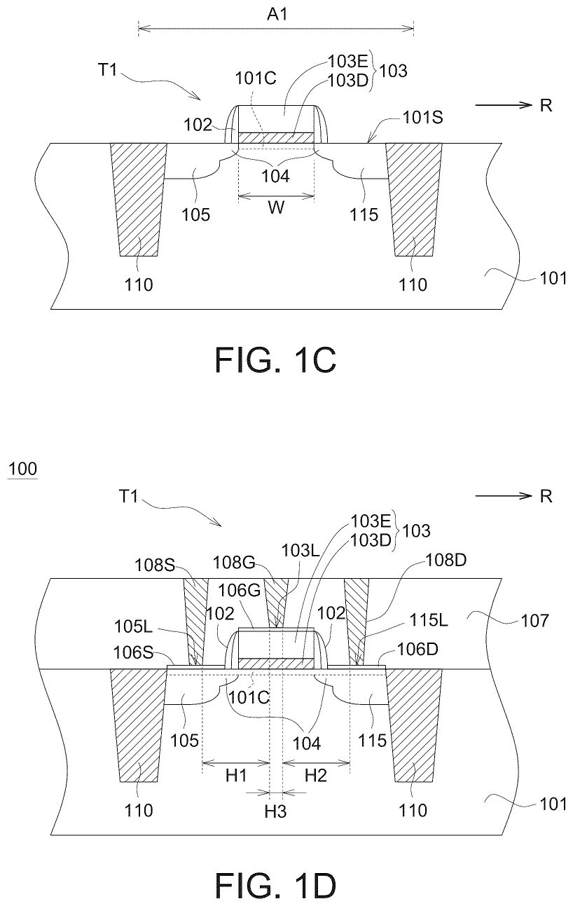

FIG. 1A to FIG. 1D are diagrams illustrating a series of process structures for fabricating a semiconductor device 100, according to one embodiment of the present disclosure. The forming of the semiconductor device 100 includes steps as follows: Firstly, a substrate 101 is provided. In some embodiments of the present disclosure, the substrate 101 can be a silicon-containing substrate, such as a silicon wafer, silicon-on-insulator (SOI), or other semiconductor substrates. In some alternative embodiments of the present disclosure, the substrate 101 may be made of, for example, germanium (Ge), or a compound semiconductor material, such as gallium arsenide (GaAs). In the present embodiment, the substrate 101 can be a silicon wafer.

Next, a shallow trench isolation structure (STI) 110 is formed in the (semiconductor) substrate 101 to define a device region A1 in the semiconductor substrate 101. In the present embodiment, the forming of the STI 110 includes steps as follows: Firstly, a trench 110T is formed on the surface 101S of the semiconductor substrate 101 and extending into the semiconductor substrate 101 by a photoresist etching process in the substrate 101, so as define a device region A1 on the surface 101S of the semiconductor substrate 101. Then, a dielectric material is deposited on the surface 101S of the semiconductor substrate 101 by a deposition process to fill the trench 110T, and an etching back or planarization process (for example, a mechanical polishing process (CMP) process) is performed to remove the dielectric material disposed on the surface 101S of the substrate 101. The portion of the dielectric material remained in the trench 110T may serve as the STI 110 (as shown in FIG. 1A).

Next, an ion implantation process is performed on the device region A1 on the surface 101S of the semiconductor substrate 101 to form a channel doping region 101C in the semiconductor substrate 101 in the device region A1. Afterwards, a gate dielectric layer 103D is formed on the surface 101S of the semiconductor substrate 101 in the device region A1. In some embodiments of the present disclosure, the gate dielectric layer 103D may be a silicon oxide layer (but not limited to this regard) or other suitable dielectric material layer. Another ion implantation process, using the gate dielectric layer 103D as a mask, is performed on the device region A1 to form a lightly doped (LDD) region 104 in the semiconductor substrate 101 (as shown in FIG. 1B).

Subsequently, a stacked gate electrode layer 103E is formed above the gate dielectric layer 103D, and a spacer 102 made of silicon oxide and/or silicon nitride is formed on the sidewalls of the gate dielectric layer 103D and the gate electrode layer 103E, so as to form a gate structure 103. The gate structure 103 is disposed above the channel doping region 101C, and the area of the gate structure 103 is substantially the same as the area of the channel doping region 101. The width of the spacer 102 is substantially between 0.01 micrometer (μm) and 0.1 μm.

Another ion implantation process, using the gate structure 103 as a mask, is performed on the device region A1 on the surface 101S of the semiconductor substrate 101 to form a source region 105 and a drain region 115 in the semiconductor substrate 101 within the device region A1, both are respectively adjacent to the gate structure 103 and electrically contact with the LDD region 104. In the present embodiment, the channel doping region 101C, the gate structure 103, the LDD region 104, the source region 105 and the drain region 115 are combined to form a metal-oxide semiconductor field-effect transistor (MOSFET) unit T1. As shown in FIG. 1C, the source region 105 and the drain region 115 are respectively adjacent to opposite sides of the channel doping region 101C; and the channel doping region 101C has a width W (measured from the edge of the source region 105 to the edge of the drain region 115) greater than 0.5 μm.

Afterwards, metal silicide layers 106G, 106S and 106D are respectively formed on the surfaces of the gate electrode layer 103E, the source region 105 and the drain region 115 through a metal silicide growth process. And an inter-layer dielectric layer (ILD) 107 is formed to cover on the MOSFET unit T1. Then, a gate contact structure 108G, a source contact structure 108S, and a drain contact structure 108D are respectively formed in the ILD 107 to form the semiconductor device 100 as shown in FIG. 1D.

For example, in some embodiments of the present disclosure, the gate contact structure 108G, the source contact structure 108S and the drain contact structure 108D may be metal plugs respectively formed in the ILD 107 through a damascene process. Plug. Wherein, the gate contact structure 108G lands on the gate structure 103 and electrically contacts with the gate electrode layer 103E (through the metal silicide layer 106G), and the contact interface between these two jointly defines a gate landing region 103L. The source contact structure 108S lands on the source region 105 and electrically contacts with the source region 105 (through the metal silicide layer 106S), and the contact interface between these two jointly defines a source landing region 105L. The drain contact structure 108D lands on the drain region 115 and electrically contacts with the drain region 115 (through the metal silicide layer 106D), and the contact interface between these two jointly defines a drain landing region 115L.

In some embodiments of the present disclosure, the distance H1 separated from the source landing region 105L to the gate landing region 103L and the distance H2 separated from the drain landing region 115L to the gate landing region 103L may be equal or different. For example, in the present embodiment, the distances H1 and H2 separated from the gate landing region 103L respectively to the source landing region 105L drain landing region 115L are the same, both are substantially greater than or equal to 0.1 μm (H1=H2>0.1 μm).

The area of the gate landing region 103L is substantially less than or equal to the area of the gate structure 103; the area of the source landing region 105L is substantially less than or equal to the area of the source region 105; the area of the drain landing region 115L is substantially less than or equal to the area of the source region 105 Less than or equal to the area size of the drain region 115. In the present embodiment, the area of the gate structure 103 may be 0.3 square microns (μm²); the area of the source region 105 and the drain region 115 may be 0.72 μm² respectively.

Since the length and width H3 of the gate landing region 103L are smaller than the channel length L of the channel doping region 101C (for example, substantially ranging from 0.5 μm to 10 μm, and preferably being 1 μm), thus overlapping the gate landing region 103L to the gate structure 103 (over the channel doping region 101C) does not change the channel length L, nor shorten the width W (for example, 0.3 microns) of the gate structure 103. Such that, it does not increase the leakage current of the MOSFET unit T1, nor affect the alignment accuracy between the gate contact structure 108G and the gate structure 103.

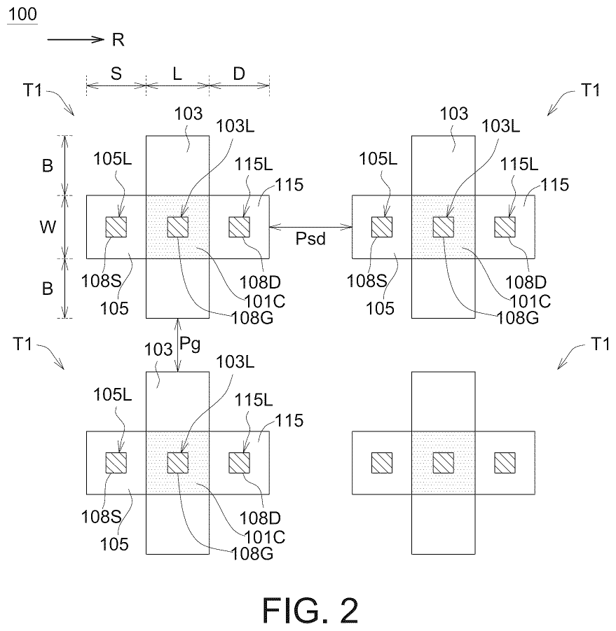

FIG. 2 is a top view illustrating the structure of the semiconductor device 100 as depicted in FIG. 1D. The semiconductor device 100 includes an MOSFET unit array formed by four MOSFET units T1. Wherein, the gate landing region 103L of each transistor unit T1 at least partially overlaps with the channel doping region 101C thereof. The gate landing region 103L and the source landing region 105L at least partially overlap along the arranging direction R of the source region 105 and the drain region 115. Moreover, the gate landing region 103 and the drain landing region 115L also at least partially overlap along the direction R.

The length of each MOSFET units T1 (of the semiconductor device 100), measured along a direction perpendicular to the direction R, may include the width W of the channel doping region 101C, and the redundant length B protruding from both sides of the channel doping region 101C (substantially ranging from 0.03 μm to 0.16 μm) and the pitch Pg (substantially ranging from 0.06 to and 0.21 μm) of the adjacent two gate structures 103, which is the sum of W, 2×B and Pg (W+2×B+Pg). The length of the MOSFET units T1, measured along a direction parallel to the direction R, may include may the sum of the length L of the channel doping region 101C, the width S of the source region 105, the width D of the drain region 115, and the spacing Psd (substantially ranging from 0.12 μm to and 0.21 μm) between the adjacent source region 105 and the drain region 115 (which is L+S+D+Psd).

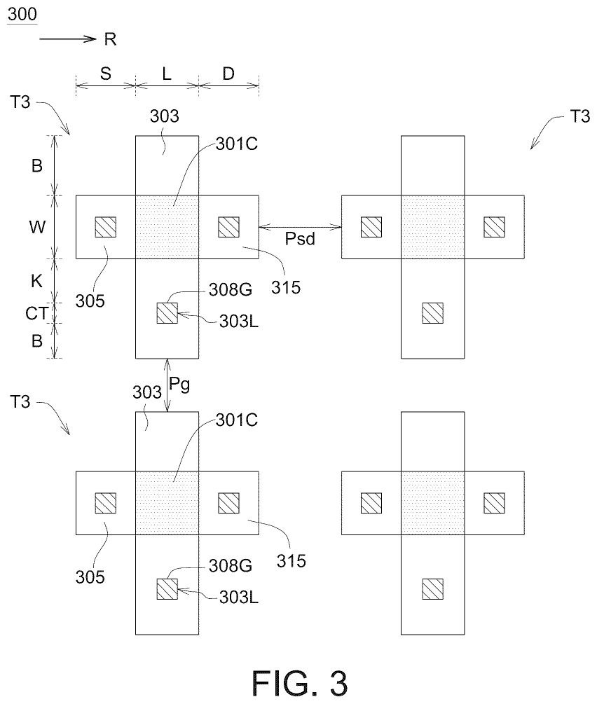

Comparing with the interlayer interconnection structure of a traditional semiconductor device 300 (referring to FIG. 3, FIG. 3 is a top view illustrating the structure of a traditional semiconductor device 300), science the gate contact structure 308G of the MOSFET unit T3 (applied in the traditional semiconductor device 300) is disposed outside the channel doping region 301C (and electrically contacts with the gate landing region 303L of the gate structure 303), thus the length of the gate structure 303 of the MOSFET unit T3, measured along the direction perpendicular to the direction R, not only includes the width W of the channel doping region 301C, the redundant length B protruding from both sides of the channel doped region 301C, and the spacing Pg of the adjacent two gate structures 303, but also includes an additional extending width K outwardly extending from the gate structure 303 for accommodating the gate landing area 303L, and the overlap width of the gate structure 303 and the gate landing area 303L (ie, the width CT of the gate landing area 303L).

Assume that the widths of the channel doping regions 101C and 301C of the MOSFET units T1 and T3 are equal (both are W); the spacing between adjacent two gate structures 103 and the spacing between adjacent two gate structures 303 are equal (Both are Pg); the redundant lengths of the gate structure 103 protruding from both sides of the channel doped regions 103C and 301C are equal (both are B). Then the length of the traditional MOSFET unit T3, measured along the direction perpendicular to the direction R, must be expanded to W+2B+Pg+CT+K. The lengths of the transistor units T3 and T1, measured along the direction parallel to the direction R, both include the length L of the channel doping region 301C, the width S of the source region 305, the width D of the drain region 315, and the distances Psd between the adjacent source region 305 and the drain region 315 (which is L+S+D+Psd).

The area of the MOSFET unit T3 is (W+2B+Pg+CT+K)×(L+S+D+Psd), which is still much larger than the area of the MOSFET unit T1 (W+2B+Pg)×(L+S+D+Psd). It can be seen that the area of the MOSFET T1 can be significantly reduced by changing the position of the gate contact landing region 103L, thereby the area of the semiconductor device 100 applying the MOSFET units T1 can be minimized.

It should be appreciated that although the semiconductor device 100 (as shown in FIG. 1D) only includes one MOSFET unit T1, but it is just illustrative for describing the present invention. The technical content and the structure of the semiconductor device 100 are not limited thereto. For example, in some other embodiments of the present disclosure, the semiconductor device 100 can include a plurality of transistor units (not shown) that are the same as or different from the MOSFET unit T1.

In accordance with the aforementioned embodiments of the present disclosure, a semiconductor device and a method for fabricating the same are provided, wherein the semiconductor device includes a transistor having a gate landing region, a source landing region and a drain landing region, and each of these three at least partially overlaps with a channel doping region of the transistor. By changing the position of a gate landing region in a manner of at least partially overlapping the channel doping region of the transistor, the gate landing region can at least partially overlap with at least one of the source landing region and the drain landing region in an arranging direction of the source region and the drain region without changing the width of the channel doping region and without shortening the width of the gate region.

Since this approach neither changes the width of the channel doping region nor shortens the width of the gate region, while the gate width of the transistor is reduced, thus the length of the gate structure of the transistor can be reduced without increasing the current leakage of the transistor and without affecting the alignment accuracy of the gate contact structure thereof. Such that the overall size of semiconductor device applying the transistor can be minimized.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a gate structure, disposed on the substrate
a source region, disposed in the substrate
a drain region, disposed in the substrate
a gate contact structure, landing on a gate landing region over the gate structure and electrically contacting with the gate structure;
a source contact structure, landing on a source landing region over the source region and electrically contacting with the source region; and
a drain contact structure, landing on a drain landing region over the drain region and electrically contacting with the drain region;
wherein, at least one of the source landing region and the drain landing region at least partially overlaps with the gate landing region in an arranging direction of the source region and the drain region.

2. The semiconductor device according to claim 1, wherein the substrate comprises a channel doping region, the gate structure is disposed above the channel doping region, and the source region and the drain region are respectively disposed adjacent to opposite sides of the channel doping region.

3. The semiconductor device according to claim 1, wherein the gate landing region has an area smaller than that of the channel doping region, and the gate landing region at least partially overlaps with the channel doping region.

4. The semiconductor device according to claim 1, wherein the channel doping region has a width greater than 0.5 microns (μm).

5. The semiconductor device according to claim 1, wherein the gate structure comprises a gate electrode; and the gate electrode has a width substantially greater than 0.3 μm.

6. The semiconductor device according to claim 1, wherein at least one of the source landing region and the drain landing region has a distance substantially greater than 0.1 μm separated from the gate landing region.

7. The semiconductor device according to claim 1, further comprising a dielectric layer covering the gate structure, the source region and the drain region; wherein the gate landing region, the drain landing region and the drain landing region are respectively a portion of the gate structure, a portion of the source region and a portion of the drain region exposed from openings passing through in the dielectric layer.

8. A method for fabricating a semiconductor device, comprising:
providing a substrate;
forming a gate structure on the substrate;
forming a source region and a drain region in the substrate;
forming a gate contact structure landing on a gate landing region above the gate structure, and electrically contacting with the gate structure;
forming a source contact structure landing on a source landing region above the source region, and electrically contacting with the source region; and
forming a drain contact structure landing on a drain landing region above the drain region, and electrically contacting with the drain region;
wherein at least one of the source landing region and the drain landing region at least partially overlaps with the gate landing region in an arranging direction of the source region and the drain region.

9. The method according to claim 8, further comprising forming a channel doping region in the substrate to make the gate structure disposed above the channel doping region, and to make the source region and the drain region respectively disposed adjacent to opposite sides of the channel doping region.

10. The method according to claim 8, wherein the forming of the gate contact structure, the source contact structure and the drain contact structure comprises:
forming a dielectric layer covering on the gate structure, the source region and the drain region; and
etching the dielectric layer to form a first opening exposing a portion of the gate structure to define the gate landing region; to form a second opening exposing a portion of the source region to define the source landing region; and to form a third opening exposing a portion of the drain region to define the drain landing region.
